(19) United States
(12) Patent Application Publication
(10) Pub. No.: US 2025/0351445 A1
(43) Pub. Date: Nov. 13, 2025

(54) UNIFORM SIGE CHANNEL FORMATION FOR GAA PMOS

(71) Applicant: Applied Materials, Inc., Santa Clara, CA (US)

(72) Inventors: Sai Hooi Yeong, Cupertino, CA (US); Benjamin Colombeau, San Jose, CA (US); Balasubramanian Pranatharthiharan, San Jose, CA (US)

(73) Assignee: Applied Materials, Inc., Santa Clara, CA (US)

(21) Appl. No.: 18/659,527

(22) Filed: May 9, 2024

(51) Int. Cl. H01L 29/423; H01L 21/8238; H01L 27/092; H01L 29/06; H01L 29/15; H01L 29/66; H01L 29/775; H01L 29/786

(52) U.S. Cl. CPC H10D 30/6735; H10D 30/014; H10D 30/43; H10D 30/6757; H10D 62/121; H10D 62/815; H10D 64/017; H10D 84/0167; H10D 84/0177; H10D 84/038; H10D 84/85

(57) ABSTRACT

A method of forming a semiconductor device, the method including forming a superlattice structure on a substrate, the superlattice structure including a plurality of first layers and a corresponding plurality of second layers, the first layers and the second layers being alternatingly arranged in a plurality of stacked pairs; forming one or more gate and gate spacers in a gate region on the substrate; forming a plurality of nanosheets from the superlattice structure; filling the corresponding plurality of voids with a plurality of dummy dielectric interlayers; etching the plurality of nanosheets between the one or more gate and gate spacers to form one or more source regions and one or more drain regions; forming an inner spacer on the plurality of dummy dielectric interlayers; and depositing a source material in the one or more source regions and a drain material in the one or more drain regions.

### TECHNICAL FIELD

Embodiments of the disclosure generally relate to methods of forming electronic devices. More specifically, embodiments of the disclosure relate to methods of forming gate all around device structures.

### BACKGROUND

The transistor is a key component of most integrated circuits. Since the drive current, and therefore speed, of a transistor is proportional to the gate width of the transistor, faster transistors generally require larger gate width. Thus, there is a trade-off between transistor size and speed, and “fin” field-effect transistors (finFETs) have been developed to address the conflicting goals of a transistor having maximum drive current and minimum size. FinFETs are characterized by a fin-shaped channel region that greatly increases the size of the transistor without significantly increasing the footprint of the transistor, and are now being applied in many integrated circuits. However, finFETs have their own drawbacks.

As the feature sizes of transistor devices continue to shrink to achieve greater circuit density and higher performance, there is a need to improve transistor device structure to improve electrostatic coupling and reduce negative effects such as parasitic capacitance and off-state leakage. Examples of transistor device structures include a planar structure, a fin field effect transistor (FinFET) structure, and a gate all around (GAA) structure. The GAA device structure includes several lattice matched channels suspended in a stacked configuration and connected by source/drain regions. The GAA structure provides good electrostatic control and may find broad adoption in complementary metal oxide semiconductor (CMOS) wafer manufacturing.

The formation of the channel region of GAA includes forming a series of nanosheets across the channel, where the nanosheets may be arranged in a parallel orientation and each nanosheet separated from each neighboring nanosheet by a space or “void.” The formation of the uniform SiGe channel nanosheets through cladding SiGe epitaxy often includes steps such as dry oxidation or annealing that can be performed at severe conditions such as temperatures of 600° C. or higher. At these temperatures, dopants from the source and/or drain region, including boron and phosphorus ions, can migrate into the channel region and cause undesirable effects, including drain-induced barrier lowering (DIBL) which reduces voltage across the gate and can short the electronic device. The DIBL often requires re-optimization of the source/drain-gate junction, and also limits junction overlap windows. Dopant migration into the channel limits the type and severity of annealing options that could be advantageously used to form the nanosheets through the channel region. These effects become larger as transistor sizes continue to decrease.

Accordingly, there is a need for improved methods of forming GAA transistors that avoid DIBL and also open up new options for high-temperature processing and treatment steps during nanosheet formation across the GAA channel region.

### SUMMARY

The present disclosure provides methods of forming semiconductor devices. In one or more embodiments, SiGe channel formation occurs before the deposition of the source and drain regions. In one or more embodiments, a method of forming a semiconductor device is provided, the method comprising forming a superlattice structure on a substrate, the superlattice structure comprising a plurality of first layers of a first material and a corresponding plurality of second layers of a second material, the first layers and the second layers being alternatingly arranged in a plurality of stacked pairs; forming one or more gate and gate spacers in a gate region on the substrate and the superlattice structure; forming a plurality of nanosheets from the superlattice structure, the plurality of nanosheets separated by a corresponding plurality of voids between each nanosheet; filling the corresponding plurality of voids with a plurality of dummy dielectric interlayers; etching the plurality of nanosheets between the one or more gate and gate spacers to form one or more source regions and one or more drain regions; forming an inner spacer on the plurality of dummy dielectric interlayers; and depositing a source material in the one or more source regions and a drain material in the one or more drain regions.

In one or more embodiments, a method of forming a semiconductor device is provided, the method including: forming a superlattice structure on a substrate, the superlattice structure comprising a plurality of first layers of a first material and a corresponding plurality of second layers of a second material, the first layers and the second layers being alternatingly arranged in a plurality of stacked pairs; forming one or more gate and gate spacers in a gate region on the substrate and the superlattice structure; etching the superlattice structure between the one or more gate and gate spacers to form an etched superlattice structure, and to form one or more source regions and one or more drain regions; forming a plurality of nanosheets from the etched superlattice structure, the plurality of nanosheets separated by a corresponding plurality of voids between each nanosheet; filling the corresponding plurality of voids with a plurality of dummy dielectric interlayers; forming an inner spacer on the plurality of dummy dielectric interlayers; and depositing a source material in the one or more source regions and a drain material in the one or more drain regions.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a process flow diagram of a method of forming a semiconductor device according to one or more embodiments of the present disclosure;

FIGS. 2A-2N illustrate stages of fabrication of a substrate during methods of forming a semiconductor device according to one or more embodiments;

FIG. 3 illustrates a process flow diagram of a method of forming a semiconductor device according to one or more embodiments;

FIGS. 4A-4O illustrate stages of fabrication of a substrate during methods of forming a semiconductor device according to one or more embodiments; and

FIG. 5 illustrates a schematic representation of a cluster tool according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

As used in this specification and the appended claims, the terms “precursor”, “reactant”, “reactive gas” and the like are used interchangeably to refer to any gaseous species that can react with the substrate surface.

Transistors are circuit components or elements that are often formed on semiconductor devices. Depending upon the circuit design, in addition to capacitors, inductors, resistors, diodes, conductive lines, or other elements, transistors are formed on a semiconductor device. Generally, a transistor includes a gate formed between source and drain regions. In one or more embodiments, the source and drain regions include a doped region of a substrate and exhibit a doping profile suitable for a particular application. The gate is positioned over the channel region and includes a gate dielectric interposed between a gate electrode and the channel region in the substrate.

As used herein, the term “field effect transistor” or “FET” refers to a transistor that uses an electric field to control the electrical behavior of the device. Enhancement mode field effect transistors generally display very high input impedance at low temperatures. The conductivity between the drain and source terminals is controlled by an electric field in the device, which is generated by a voltage difference between the body and the gate of the device. The FET's three terminals are source(S), through which the carriers enter the channel; drain (D), through which the carriers leave the channel; and gate (G), the terminal that modulates the channel conductivity. Conventionally, current entering the channel at the source(S) is designated Is and current entering the channel at the drain (D) is designated ID. Drain-to-source voltage is designated VDs. By applying voltage to gate (G), the current entering the channel at the drain (i.e. ID) can be controlled.

The metal-oxide-semiconductor field-effect transistor (MOSFET) is a type of field-effect transistor (FET). It has an insulated gate, whose voltage determines the conductivity of the device. This ability to change conductivity with the amount of applied voltage is used for amplifying or switching electronic signals. A MOSFET is based on the modulation of charge concentration by a metal-oxide-semiconductor (MOS) capacitance between a body electrode and a gate electrode located above the body and insulated from all other device regions by a gate dielectric layer. Compared to the MOS capacitor, the MOSFET includes two additional terminals (source and drain), each connected to individual highly doped regions that are separated by the body region. These regions can be either p or n type, but they are both be of the same type, and of opposite type to the body region. The source and drain (unlike the body) are highly doped as signified by a “+” sign after the type of doping.

If the MOSFET is an n-channel or nMOS FET, then the source and drain are n+ regions and the body is a p region. If the MOSFET is a p-channel or pMOS FET, then the source and drain are p+ regions and the body is an n region. The source is so named because it is the source of the charge carriers (electrons for n-channel, holes for p-channel) that flow through the channel; similarly, the drain is where the charge carriers leave the channel.

As used herein, the term “fin field-effect transistor (FinFET)” refers to a MOSFET transistor built on a substrate where the gate is placed on two or three sides of the channel, forming a double- or triple-gate structure. FinFET devices have been given the generic name FinFETs because the channel region forms a “fin” on the substrate. FinFET devices have fast switching times and high current density.

As used herein, the term “gate all-around (GAA),” is used to refer to an electronic device, e.g. a transistor, in which the gate material surrounds the channel region on all sides. The channel region of a GAA transistor may include nanowires or nanoslabs, bar-shaped channels, or other suitable channel configurations known to one of skill in the art (collectively termed “nanosheets” herein). In one or more embodiments, the channel region of a GAA device has multiple horizontal nanowires or horizontal bars vertically spaced, making the GAA transistor a stacked horizontal gate-all-around (hGAA) transistor.

One or more embodiments of the present disclosure are directed to methods of forming horizontal gate-all-around devices. One or more embodiments advantageously provide for forming the SiGe channel before depositing the source and/or drain (S/D) regions. In one or more embodiments, the SiGe channel is formed from a superlattice structure before depositing the S/D regions and recessing of the superlattice structure to the gate regions is performed after the formation of the SiGe nanosheets and early wire-release. In other embodiments, the SiGe channel is formed from a superlattice structure before depositing the S/D regions, and the superlattice structure is recessed to the gate regions before formation of the SiGe nanosheets and early wire-release.

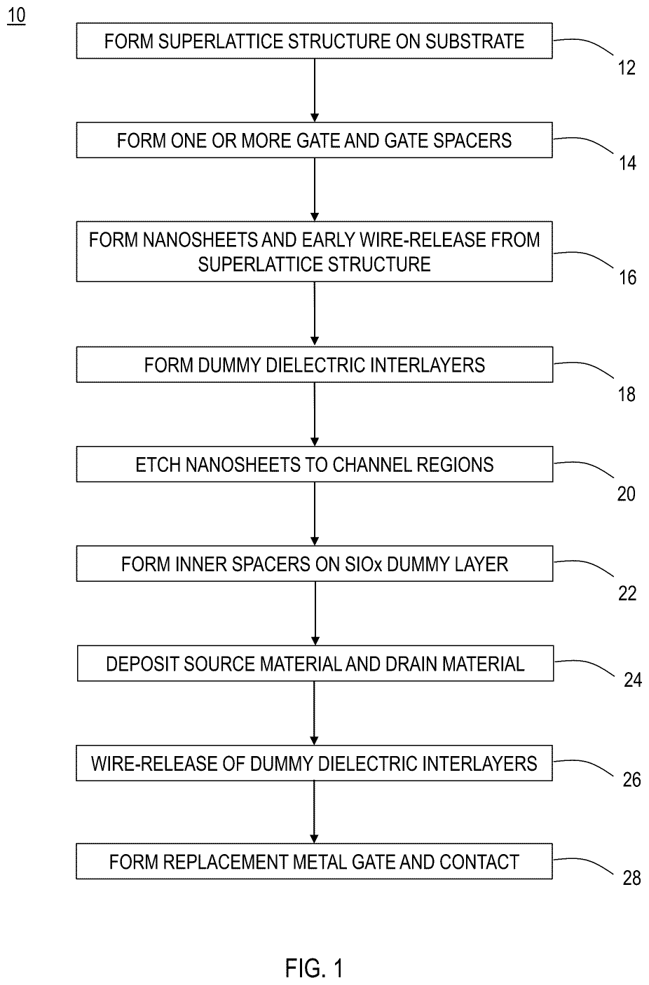

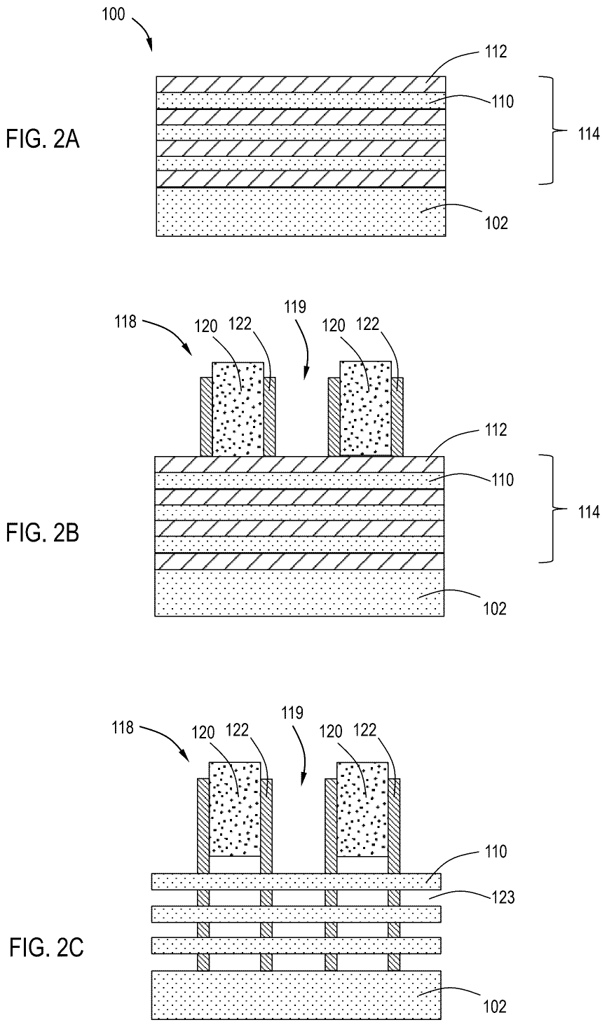

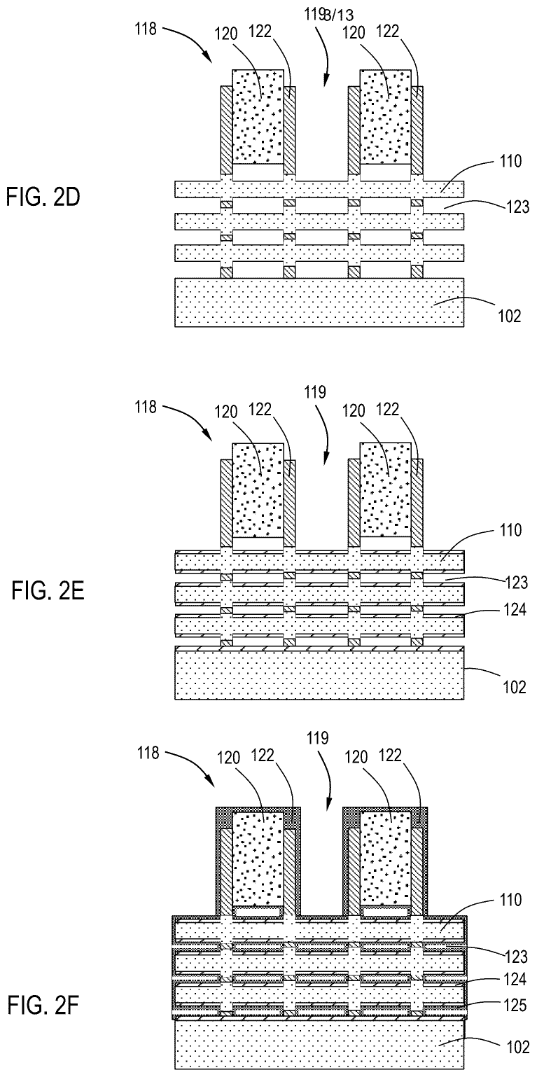

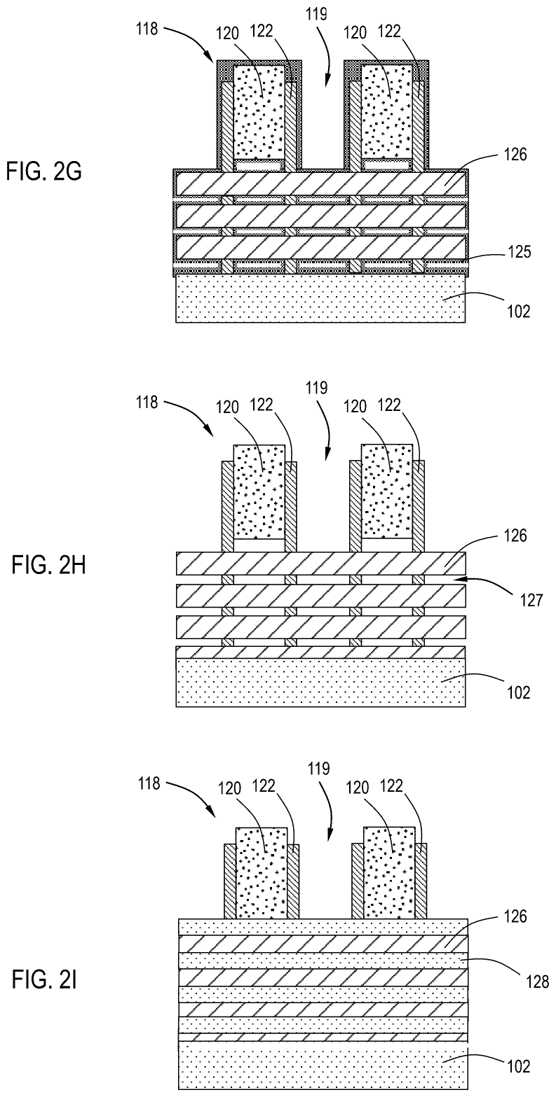

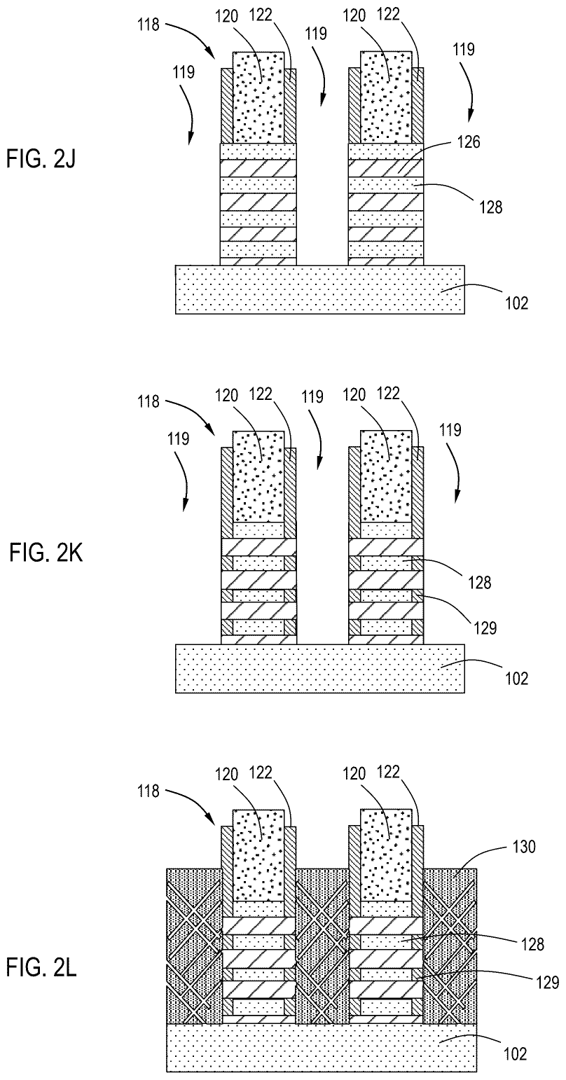

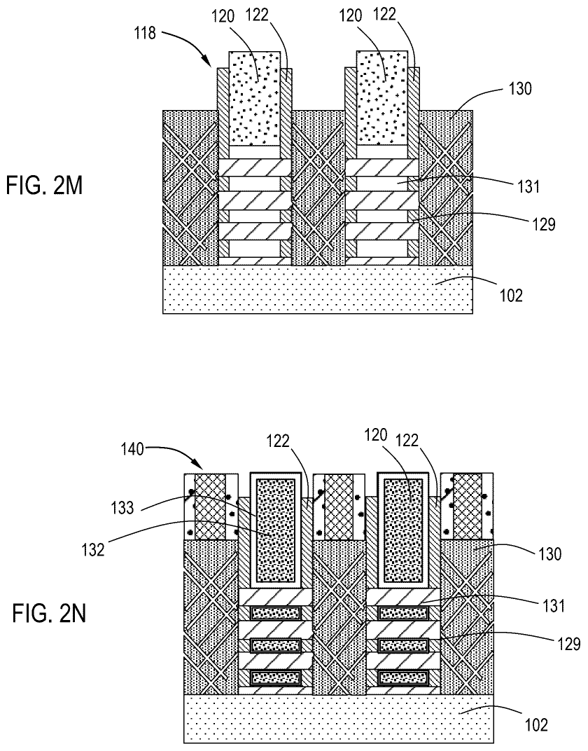

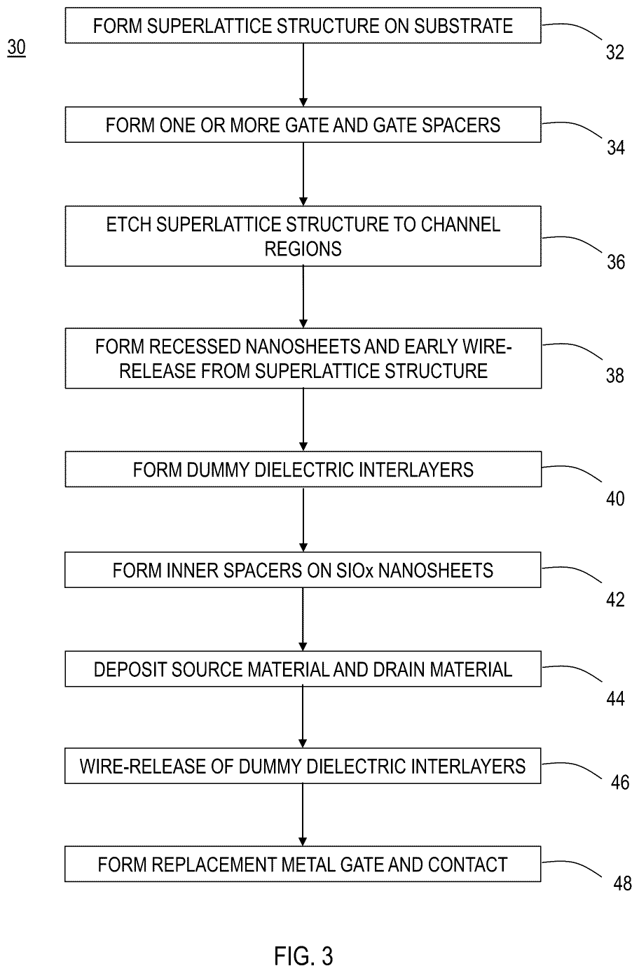

FIG. 1 illustrates a process flow diagram of a method 10 of forming a semiconductor device according to one or more embodiments. The method 10 is described below with respect to FIGS. 2A-2N, which schematically illustrate stages of fabrication of semiconductor structures according to one or more embodiments. The method 10 may be part of a multi-step fabrication process of a semiconductor device. Accordingly, the method may be performed in any suitable processing chamber coupled to a cluster tool. The cluster tool may include processing chambers for fabricating a semiconductor device, such as chambers configured for etching, deposition, physical vapor deposition (PVD), chemical vapor deposition (CVD), oxidation, or any other suitable chamber used for the fabrication of a semiconductor device. Importantly, the operations schematically illustrated in FIGS. 1 and 3 may be performed in a different order, such that the ordering shown in FIGS. 1 and 3 is not representative of all embodiments of the present disclosure.

Referring to FIG. 1, the method 10 may include operation 12, in one or more embodiments, including forming a superlattice structure on a substrate. In one or more embodiments, the substrate is a bulk semiconductor substrate. As used in this regard, the term “bulk semiconductor substrate” refers to a substrate in which the entirety of the substrate is comprised of a semiconductor material. The bulk semiconductor substrate may comprise any suitable semiconducting material and/or combinations of semiconducting materials for forming a semiconductor structure. For example, the semiconducting layer may comprise one or more materials such as crystalline silicon (e.g., Si<100> or Si<111>), silicon oxide, strained silicon, silicon germanium, doped or undoped polysilicon, doped or undoped silicon wafers, patterned or non-patterned wafers, doped silicon, germanium, gallium arsenide, or other suitable semiconducting materials. In one or more embodiments, the semiconductor material is silicon (Si). In one or more embodiments, the semiconductor material may be a doped material, such as n-doped silicon (n-Si), or p-doped silicon (p-Si). In one or more embodiments, the substrate may be doped using any suitable process such as an ion implantation process.

In one or more embodiments, the superlattice structure formed at operation 12 may have a structure as illustrated in FIG. 2A. FIG. 2A illustrates a semiconductor device 100 comprising a substrate 102 and superlattice structure 114. The superlattice structure 114 may comprise a plurality of first layers 112 and a corresponding plurality of second layers 110. The plurality of first layers 112 may comprise a first material and the corresponding plurality of second layers 110 may comprise a second material. In one or more embodiments, the first layers and the second layers are alternatingly arranged in a plurality of stacked pairs, as illustrated in FIG. 2A. In one or more embodiments, the stacked pairs are arranged horizontally. In one or more embodiments, the first material is silicon germanium (SiGe). In one or more embodiments, the second material is silicon (Si). In one or more embodiments, the first material comprises SiGe, the second material comprises Si, and a top layer of the superlattice structure comprises the first material (SiGe). In one or more embodiments, the SiGe comprises at least 25% germanium (Ge). In one or more embodiments, the amount of germanium (Ge) in the SiGe material is in a range of from 25% to 100%, including in a range of from 25% to 90%, or in a range of from 25% to 75%, or in a range of from 25% to 50% germanium. In one or more embodiments, the plurality of layers comprising SiGe are dummy dielectric interlayers.

The superlattice structure 114 may be formed by any suitable means known to the skilled artisan. In one or more embodiments, the superlattice structure 114 is formed by epitaxial growth of the plurality of first layers 112 and the plurality of second layers 110.

Referring to FIG. 1, at operation 14, in one or more embodiments, one or more gate and gate spacers are formed in a gate region on the substrate and the superlattice structure 114. FIG. 2B illustrates the one or more gate and gate spacers according to one or more embodiments, including gates 120 and gate spacers 122. The gates 120 and gate spacers 122 may define one or more gate regions 118 and one or more source/drain regions 119. In one or more embodiments, the gate 120 is a dummy poly gate. The dummy poly gate 120 may be formed using any suitable conventional deposition and patterning process known in the art. In one or more embodiments, the dummy poly gate 120 comprises one or more of tungsten (W), cobalt (Co), molybdenum (Mo), ruthenium (Ru), titanium nitride (TiN), tantalum nitride (TaN), titanium aluminum (TiAl), and N doped polysilicon. In one or more embodiments, the gate region 118 separates the source/drain region 119 from an adjacent source/drain region (not shown).

In one or more embodiments, the gate spacers 122 are formed along outer sidewalls of the dummy poly gate 120, as illustrated in FIG. 2B. The gate spacers may comprise any suitable insulating materials known in the art, for example, silicon nitride, silicon oxide, silicon oxynitride, silicon carbide, or the like. In one or more embodiments, the gate spacers 122 are formed using any suitable conventional deposition and patterning process known in the art, such as atomic layer deposition, plasma enhanced atomic layer deposition, plasma enhanced chemical vapor deposition, low-pressure chemical vapor deposition, or isotropic deposition.

Referring to FIG. 1, in one or more embodiments, at operation 16, nanosheets of the SiGe gate are formed in the superlattice structure by early wire-release of dummy SiGe and one or more of PMOS open patterning and trim, cladding SiGe epitaxy, dielectric capping, drive-in anneal, and dielectric cap removal. FIGS. 2C-2H illustrate fabrication steps of the SiGe nanosheets according to one or more embodiments.

In one or more embodiments, forming the plurality of SiGe nanosheets from the superlattice structure 114 may comprise a wire-release process to selectively etch the superlattice structure 114 to form a plurality of nanosheets 110 and a plurality of voids 123, as illustrated in FIG. 2C. The wire-release process may remove the plurality of first layers 112, where the plurality of first layers 112 may comprise dummy SiGe layers.

For example, where the superlattice structure 114 is composed of SiGe first layers 112 and Si second layers 110, the SiGe first layers 112 may be selectively etched to form channel nanosheets 110 (also referred to as channel nanowires). The released layers, for example SiGe first layers 112, may be removed using any suitable etchant that etches the first material SiGe at a significantly higher rate than the second material Si of the second layers 110. In one or more embodiments, where the first material is SiGe and is being etched, and the second material is Si, the first layers 112 of SiGe may be selectively removed using a wet etchant such as, but not limited to, aqueous carboxylic acid/nitric acid/HF solution or aqueous citric acid/nitric acid/HF solution.

In one or more embodiments, forming the SiGe nanosheets comprises an optional patterning of the nanosheets for the formation of the PMOS device, as illustrated in FIG. 2D. The skilled artisan will be familiar with the patterning process including, but not limited to, formation of a hardmask and/or photoresist layer, masking, and etching processes. The patterning can be performed at any suitable stage of method 10 and is not limited to occurring immediately after the wire-release.

In one or more embodiments, the nanosheets 110 are exposed to an optional process in which the nanosheets 110 are trimmed from an initial thickness to a reduced thickness (not shown). The nanosheets 110 may be trimmed by any suitable etch process known to the skilled artisan that is compatible with the nanosheet material, such as silicon. In one or more embodiments, the nanosheets 110 are trimmed by exposure to a wet etch process, such as aqueous alkaline media, non-limiting examples including potassium hydroxide (KOH), sodium hydroxide (NaOH), or tetramethylammonium hydroxide (TMAH) solutions. The optional trimming may result in a reduction in thickness of the nanosheets of 50% or greater. In one or more embodiments, the initial thickness of the nanosheets 110 is 4 nm to 10 nm, and the reduced thickness is 1 nm to 3 nm. In one or more embodiments, trimming the nanosheets reduces the thickness more for nanosheets that are closer to the substrate 102 than for nanosheets that are farther from the substrate 102.

In one or more embodiments, as illustrated in FIG. 2E, a cladding material 124 is formed around each of the plurality of nanosheets 110. The cladding material 124 may be formed by any suitable process known to the skilled artisan. In one or more embodiments, the cladding material 124 comprises SiGe. In one or more embodiments, the cladding material 124 is epitaxially grown on the nanosheets 110, such as via chemical vapor deposition (CVD) epitaxy in a temperature range of from about 450° C. to about 850° C. In one or more embodiments, the thickness of the cladding material 124 remains uniform around each of the plurality of nanosheets 110. In other embodiments, the thickness of the cladding material 124 may vary, such as varying inversely with the variation in thickness of the nanosheets 110. In one or more embodiments, the cladding material 124 is formed such that the cladding material closest to the substrate 102 has a thickness less than the thickness of the cladding material furthest from the substrate 102 (not shown).

As illustrated in FIG. 2F, in one or more embodiments, a dry oxidation is performed to oxidize the plurality of nanosheets 110 to form a plurality of oxide layers 125 surrounding the cladding material 124. The dry oxidation may also be referred to as dielectric capping. In one or more embodiments, the dry oxidation results in a dielectric cap layer 125 comprising SiN, SiO₂, SiON, SiOCN, or SiOC.

Dry oxidation may be performed by any suitable technique known to the skilled artisan. In one or more embodiments, the dry oxidation process is performed by exposing the semiconductor device to a rapid thermal oxidation (RTO) process. In one or more embodiments, the RTO process ramps the temperature of the substrate from a starting temperature (e.g., room temperature) to a maximum temperature in the range of from 700° C. to 1100° C. at a rate greater than or equal to 25° C./second, 50° C./second or higher, at pressures of 5 torr to 780 torr during a time period of 1 to 5 mins. During dry oxidation, in one or more embodiments, the processing environment may comprise one or more of water vapor, oxygen (O₂), ozone (O₃), or nitrogen (N₂), and, in some cases, dry oxidation may occur under a mixture of O₂/N₂ gases.

In one or more embodiments, an annealing is performed to drive in germanium (Ge) into the nanosheets 110, as illustrated schematically in FIG. 2G. As illustrated in FIG. 2G, the drive in annealing may cause the materials to reorder. In one or more embodiments, when the plurality of nanosheets 110 comprises Si and the cladding material 124 comprises SiGe, the reordering caused by the annealing may result in SiGe moving to the plurality of nanosheets 110 to form a plurality of SiGe nanosheets 126, as illustrated in FIG. 2G. The annealing may be performed in a temperature range of from about 600° C. to about 1100° C. The annealing may be performed for a time period in a range of from about 1 minute to about 30 minutes. In one or more embodiments, the annealing may comprise a rapid thermal oxidation (RTO) process. In one or more embodiments, the annealing may comprise a rapid thermal processing (RTP) or rapid thermal annealing (RTA) process to rapidly heat the semiconductor device. In one or more embodiments, the drive-in annealing results in a uniform Ge distribution across the nanosheets. In one or more embodiments, the drive-in annealing results in gradients of Ge distribution across the nanosheets.

In one or more embodiments, following annealing, the plurality of SiGe nanosheets may be surrounded by an oxide or dielectric cap 125, as illustrated schematically in FIG. 2G. In one or more embodiments, the dielectric cap 125 may be removed as illustrated in FIG. 2H. The dielectric cap 125 may be removed using any etching process known to the skilled artisan. For example, the dielectric cap 125 may be removed by either of a wet etch process or a dry etch process. After the removal of the dielectric cap 125, in one or more embodiments, a plurality of voids 127 remains between the SiGe nanosheets 126.

In one or more embodiments, a dry etch process is used, which may include a conventional plasma etch, or a remote plasma-assisted dry etch process. For example, the device may be exposed to H₂, NF₃, and/or NHs plasma species, e.g., plasma-excited hydrogen and fluorine species. In one or more embodiments, the device may undergo simultaneous exposure to H₂, NF₃, and NH₃ plasma.

In one or more embodiments, a wet etch process may include a hydrofluoric (HF) acid last process, i.e., the so-called “HF last” process, in which HF etching of surface is performed leaving surface hydrogen termination. Alternatively, any other liquid-based pre-epitaxial pre-clean process may be employed. In one or more embodiments, the oxide is removed by exposure to a dilute HF/H₂O₂ solution. In one or more embodiments the ratio of HF:H₂O₂ is from about 1:100 to about 1:150. In one or more embodiments, the process comprises a sublimation etch for native oxide removal. The etch process may be plasma or thermally based. The plasma processes can be any suitable plasma (e.g., conductively coupled plasma, inductively coupled plasma, microwave plasma).

Referring to FIG. 1, in one or more embodiments, method 10 includes an operation 18, wherein the plurality of voids 127 in the SiGe channel region are filled with a plurality of dummy dielectric interlayers 128, for example as illustrated schematically in FIG. 2I. In one or more embodiments, the plurality of dummy dielectric interlayers 128 may comprise silicon oxide (SiOx). The term “silicon oxide” or “SiOx” as used herein refers to a material comprising silicon and oxygen and does not imply any specific ratio or stoichiometry of the silicon to the oxygen. In one or more embodiments, the silicon oxide is silicon dioxide (SiO₂). In one or more embodiments, the plurality of dummy dielectric interlayers comprises one or more of SiON, SiOC, or SiOC.

The plurality of dummy dielectric interlayers 128 may be formed by any method known to the skilled artisan. For example, in one or more embodiments, the plurality of dummy dielectric interlayers is formed by an epitaxial growth of the dummy dielectric interlayer material on the SiGe nanosheets 126.

Referring to FIG. 1, in one or more embodiments, at operation 20, the plurality of nanosheets 126 and dummy dielectric interlayers 128 are etched, or recessed, between the one or more gate and gate spacers to form the one or more source/drain regions 119 as illustrated schematically in FIG. 2J. The etching or recessing may be performed by any suitable method known to the skilled artisan, such as using any of the wet or dry etching techniques described herein.

In one or more embodiments, at operation 22 of the method 10, inner spacers 129 are formed on the plurality of SiOx dummy dielectric interlayers 128. The inner spacers may be in line with the gate spacers 122 and dummy dielectric interlayers 128, as illustrated schematically in FIG. 2K. In one or more embodiments, the inner spacers 129 comprise an insulating material, such as the same insulating material as the gate spacers 122. In one or more embodiments, the inner spacers 129 comprise SiGe. In one or more embodiments, the inner spacers 129 may be formed by a deposition of the inner spacer material and etch back of the inner spacer material.

In one or more embodiments, at operation 24 of the method 10, source material and drain material 130 is deposited in the S/D regions 119, as illustrated schematically in FIG. 2L. The S/D material 130 may be deposited by any known method, such as by epitaxial growth of the S/D material 130.

In one or more embodiments, at operation 26 of method 10, the dummy dielectric interlayers are removed. For example, dummy dielectric interlayers 128 of FIG. 2L can be released by a wire-release process to form the plurality of voids 131, as illustrated schematically in FIG. 2M. The wire-release can be performed using any suitable process known to the skilled artisan, such as a dry etch or wet etch process as described herein.

Referring to FIG. 1, in one or more embodiments, at operation 28 of method 10, a replacement metal gate 132 and contact 140 are formed in the electronic device. In one or more embodiments, the replacement metal gate 132 may have a structure as shown in FIG. 2N. The replacement metal gate 132 may be formed from a conductive material such as titanium nitride, tungsten, cobalt, aluminum, or the like. The conductive material may be formed using any suitable deposition process such as atomic layer deposition in order to ensure that the replacement metal gate 132 has a uniform thickness. The replacement metal gate 132 may be surrounded by a high-k dielectric layer 133. The high-k dielectric layer 133 can be any suitable high-k dielectric material deposited by any suitable deposition method known to the skilled artisan. In one or more embodiments, the high-k dielectric material is hafnium oxide.

In one or more embodiments of the present disclosure, the SiGe channel is formed from a superlattice structure before depositing the S/D regions and recessing the superlattice structure to the gate regions is performed before formation of the SiGe nanosheets and corresponding voids from the superlattice structure.

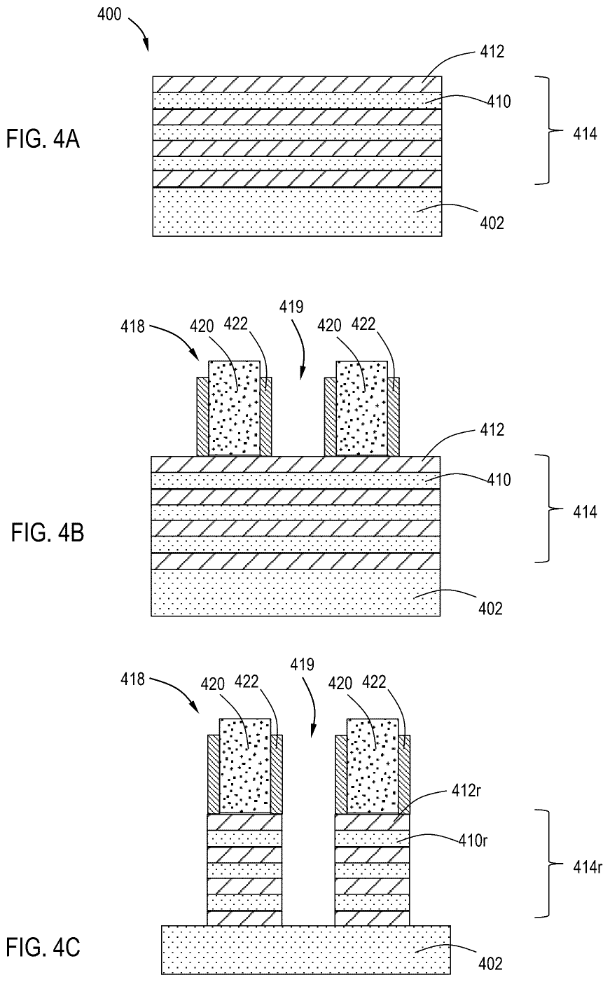

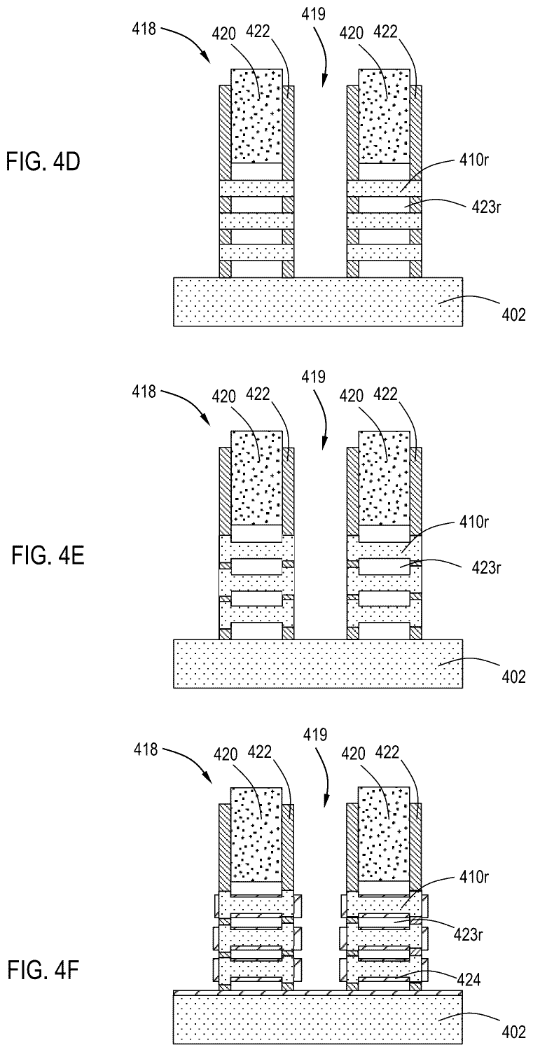

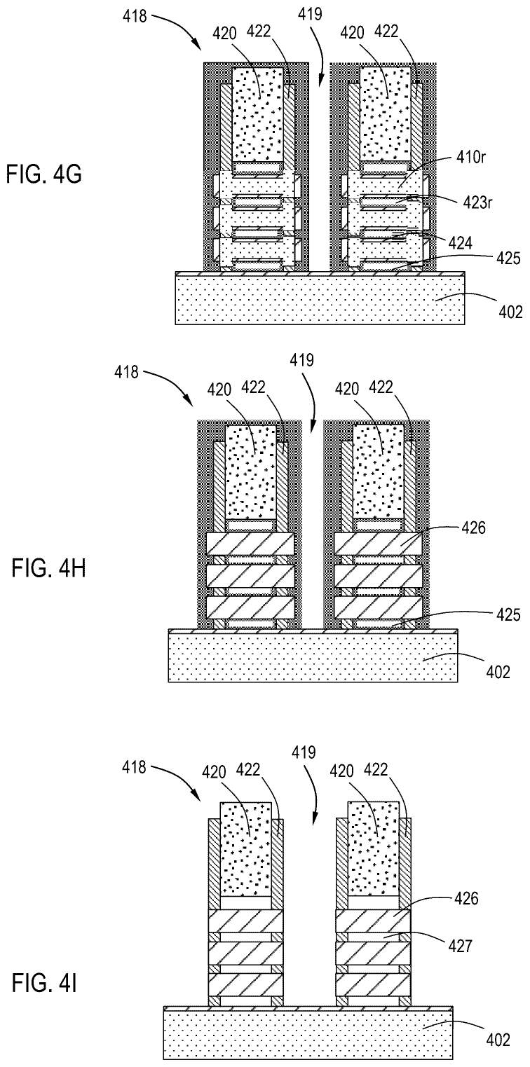

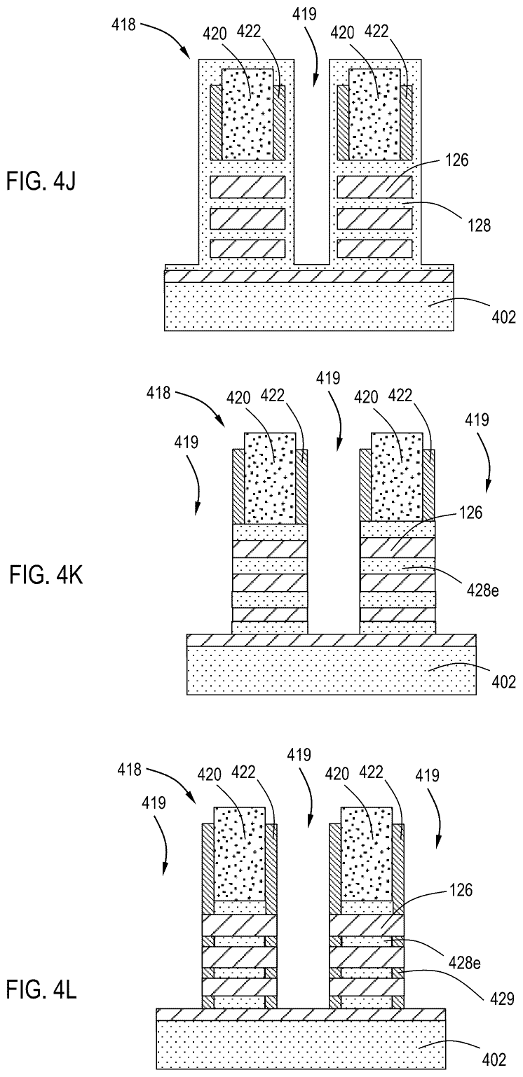

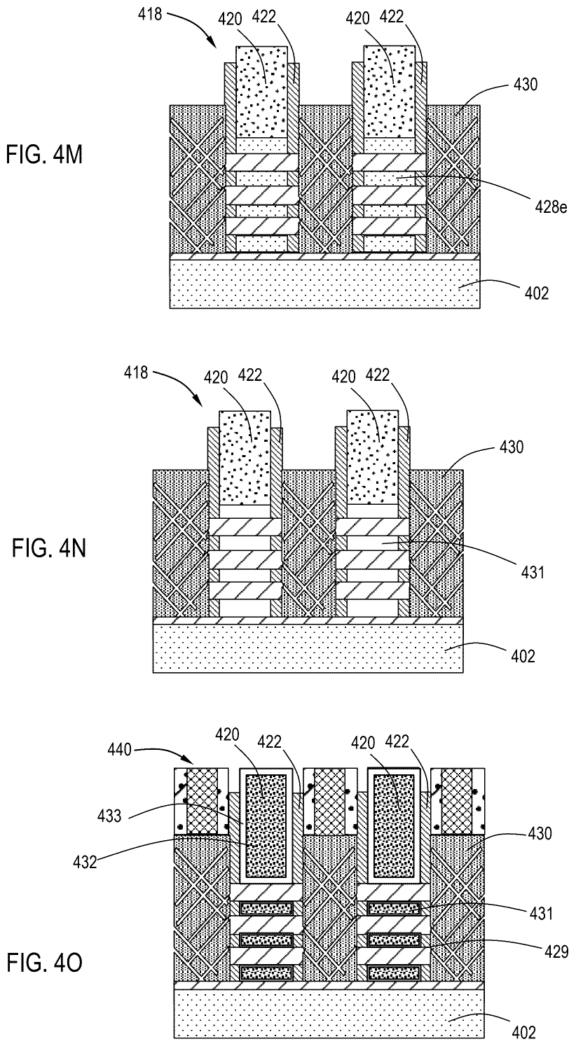

FIG. 3 illustrates a process flow diagram of a method 30 of forming a semiconductor device according to one or more embodiments. The method 30 is described below with respect to FIGS. 4A-4O, which schematically illustrate stages of fabrication of semiconductor structures according to one or more embodiments.

Referring To FIG. 3, the method 30 may include operation 32, in one or more embodiments, including forming a superlattice structure on a substrate. In one or more embodiments, the superlattice structure may have a structure as illustrated in FIG. 4A. FIG. 4A illustrates a semiconductor device 400 comprising a substrate 402 and superlattice structure 414. The superlattice structure 414 may comprise a plurality of first layers 412 and a corresponding plurality of second layers 410. The plurality of first layers 412 may comprise a first material and the corresponding plurality of second layers 410 may comprise a second material. In one or more embodiments, the first layers and the second layers are alternatingly arranged in a plurality of stacked pairs, as illustrated in FIG. 4A. In one or more embodiments, the stacked pairs are arranged horizontally. In one or more embodiments, the first material is silicon germanium (SiGe). In one or more embodiments, the second material is silicon (Si). In one or more embodiments, the first material comprises SiGe, the second material comprises Si, and a top layer of the superlattice structure comprises the first material (SiGe). In one or more embodiments, the SiGe comprises at least 25% germanium (Ge). In one or more embodiments, the amount of germanium (Ge) in the SiGe material is in a range of from 25% to 100%, including in a range of from 25% to 90%, or in a range of from 25% to 75%, or in a range of from 25% to 50% germanium. In one or more embodiments, the plurality of layers comprising SiGe are dummy SiGe layers.

The superlattice structure 414 may be formed by any suitable means known to the skilled artisan. In one or more embodiments, the superlattice structure 414 is formed by epitaxial growth of the plurality of first layers 412 and the plurality of second layers 410.

Referring to FIG. 3, at operation 34, in one or more embodiments, one or more gate 420 and gate spacers 422 are formed in a gate region 418 on the substrate and the superlattice structure 414. FIG. 4B illustrates the one or more gate 420 and gate spacers 422 according to one or more embodiments. The gates 420 and gate spacers 422 may define one or more gate regions 418 and one or more source/drain regions 419. In one or more embodiments, the gate 420 is a dummy poly gate. The dummy poly gate 420 may be formed using any suitable conventional deposition and patterning process known in the art. In one or more embodiments, the dummy poly gate 420 comprises one or more of tungsten (W), cobalt (Co), molybdenum (Mo), ruthenium (Ru), titanium nitride (TiN), tantalum nitride (TaN), titanium aluminum (TiAl), and N doped polysilicon. In one or more embodiments, the gate region 418 separates the source/drain region 419 from an adjacent source/drain region (not shown).

In one or more embodiments, the gate spacers 422 are formed along outer sidewalls of the dummy poly gate 420, as illustrated in FIG. 4B. The gate spacers 422 may comprise any suitable insulating materials known in the art, for example, silicon nitride, silicon oxide, silicon oxynitride, silicon carbide, or the like. In one or more embodiments, the sidewall spacers 422 are formed using any suitable conventional deposition and patterning process known in the art, such as atomic layer deposition, plasma enhanced atomic layer deposition, plasma enhanced chemical vapor deposition, low-pressure chemical vapor deposition, or isotropic deposition.

Referring to FIG. 3, in one or more embodiments, at operation 36, the superlattice structure 414 is globally recessed to the gate regions 418, for example as illustrated schematically in FIG. 4C. In one or more embodiments, the superlattice structure 414 is etched to form recessed superlattice structure 414r, with a recessed plurality of first layers 412r and a recessed plurality of second layers 410r.

Referring to FIG. 3, in one or more embodiments, at operation 38, recessed nanosheets and recessed voids 423r are formed from the recessed superlattice structure 414r, as illustrated schematically in FIGS. 4D-4I.

For example, where the recessed superlattice structure 414r is composed of SiGe first layers 412 and Si second layers 410, the SiGe first layers 412 may be selectively etched (i.e., removed) to form the recessed channel nanosheets 410r and corresponding plurality of voids 423r, as illustrated schematically in FIG. 4D. The released layers, for example SiGe first layers 412, may be removed using any etchant that etches the first material SiGe at a significantly higher rate than the second material Si. In one or more embodiments, where the first material is SiGe and is being etched, and the second material is Si, the layers of SiGe may be selectively removed using a wet etchant such as, but not limited to, aqueous carboxylic acid/nitric acid/HF solution or aqueous citric acid/nitric acid/HF solution.

In one or more embodiments, the forming the recessed SiGe nanosheets comprises an optional patterning of the nanosheets for the formation of the PMOS device, as illustrated in FIG. 4E. The skilled artisan will be familiar with the patterning process including, but not limited to, formation of a hardmask and/or photoresist layer, masking, and etching processes. The patterning can be performed at any suitable stage of method 10 and is not limited to occurring immediately after the wire-release.

In one or more embodiments, the recessed nanosheets 410r are exposed to an optional process in which the nanosheets 410r of FIG. 4E are trimmed from an initial thickness to a reduced thickness (not shown). The nanosheets 410r may be trimmed by any suitable etch process known to the skilled artisan that is compatible with the nanosheet material, such as silicon. In some embodiment, the nanosheets 410r are trimmed by exposure to a wet etch process, such as aqueous alkaline media, non-limiting examples including KOH, NaOH, or TMAH solutions. The optional trimming may result in a reduction in thickness of the nanosheets of 50% or greater. In one or more embodiments, the initial thickness of the nanosheets 410r is 4 nm to 10 nm, and the reduced thickness is 1 nm to 3 nm. In one or more embodiments, trimming the nanosheets reduces the thickness more for nanosheets that are closer to the substrate 402 than for nanosheets that are farther from the substrate 402.

In one or more embodiments, as illustrated in FIG. 4F, a cladding material 424 may be formed around each of the recessed nanosheets 410r. The cladding material 424 may be formed by any suitable process known to the skilled artisan. In one or more embodiments, the cladding material 424 comprises SiGe. In one or more embodiments, the cladding material 424 is epitaxially grown on the recessed nanosheets 410r, such as via chemical vapor deposition (CVD) epitaxy in a temperature range of from about 450° C. to about 850° C. In one or more embodiments, the thickness of the cladding material 424 remains uniform around each of the plurality of nanosheets 410r. In other embodiments, the thickness of the cladding material 424 may vary, such as varying inversely with the variation in thickness of the nanosheets 410r. In one or more embodiments, the cladding material 424 is formed such that the cladding material closest to the substrate 402 has a thickness less than the thickness of the cladding material furthest from the substrate 402 (not shown).

As illustrated in FIG. 4G, in one or more embodiments, a dry oxidation is performed to oxidize the plurality of recessed nanosheets 410r to form a plurality of oxide layers 425 surrounding the cladding material 424. The dry oxidation may also be referred to as a dielectric capping. In one or more embodiments, the dry oxidation results in a dielectric cap layer 425 comprising one or more of SiN, SiO₂, SiON, SiOCN, or SiOC.

Dry oxidation may be performed by any suitable technique known to the skilled artisan. In one or more embodiments, the dry oxidation process is performed by exposing the semiconductor device to a rapid thermal oxidation (RTO) process. In one or more embodiments, the RTO process ramps the temperature of the substrate from a start temperature (e.g., room temperature) to a maximum temperature in the range of 700° C. to 1100° C. at a rate greater than or equal to 25° C./second, 50° C./second or higher, at pressures of 5 to 780 torr during a time period of 1 to 5 mins. During dry oxidation, in one or more embodiments, the process environment may comprise one or more of water vapor, oxygen (O₂), ozone (O₃), or nitrogen (N₂), and in some cases dry oxidation may occur under a mixture of O₂/N₂ gases.

In one or more embodiments, an annealing is performed to drive in Ge into the recessed nanosheets 410r, as illustrated schematically in FIG. 4H. As illustrated in FIG. 4H, the drive in annealing may cause the materials to reorder. In one or more embodiments, when the plurality of recessed nanosheets 410r comprises Si and the cladding material 424 comprises SiGe, the reordering caused by the annealing may result in SiGe moving into the plurality of recessed nanosheets 410r to form a plurality of SiGe nanosheets 426. The annealing may be performed in a temperature range of from about 600° C. to about 1100° C. The annealing may be performed for a time period in a range of from about 1 minute to about 30 minutes. In one or more embodiments, the annealing may comprise a rapid thermal oxidation (RTO) process. In one or more embodiments, the annealing may comprise a rapid thermal processing (RTP) or rapid thermal annealing (RTA) process to rapidly heat the semiconductor device.

In one or more embodiments, following annealing, the plurality of SiGe nanosheets may be surrounded by a thin layer of dielectric cap or oxide 425 as illustrated schematically in FIG. 4H. In one or more embodiments, the dielectric cap 425 is removed, as illustrated schematically in FIG. 4I. The dielectric cap 425 may be removed using any etching process known to the skilled artisan. For example, it may be removed by either of a wet etch process or a dry etch process.

In one or more embodiments, a dry etch process is used to remove the dielectric cap 425, which may include a conventional plasma etch, or a remote plasma-assisted dry etch process. For example, the device may be exposed to H₂, NF₃, and/or NHs plasma species, e.g., plasma-excited hydrogen and fluorine species. In one or more embodiments, the device may undergo simultaneous exposure to H₂, NF₃, and NH₃ plasma.

In one or more embodiments, a wet etch process may include a hydrofluoric (HF) acid last process, i.e., the so-called “HF last” process, in which HF etching of surface is performed leaving surface hydrogen termination. Alternatively, any other liquid-based pre-epitaxial pre-clean process may be employed. In one or more embodiments, the oxide is removed by exposure to a dilute HF/H₂O₂ solution. In one or more embodiments the ratio of HF:H₂O₂ is from about 1:100 to about 1:150. In one or more embodiments, the process comprises a sublimation etch for native oxide removal. The etch process may be plasma or thermally based. The plasma processes can be any suitable plasma (e.g., conductively coupled plasma, inductively coupled plasma, microwave plasma). In one or more embodiments, the dielectric capping leaves a plurality of voids 427.

Referring to FIG. 3, in one or more embodiments, method 30 includes an operation 40, wherein the plurality of voids 427 in the SiGe channel region are filled with a plurality of dummy dielectric interlayers 428, as illustrated schematically in FIG. 4J. In one or more embodiments, the plurality of dummy dielectric interlayers 428 may comprise silicon oxide (SiOx). The term “silicon oxide” or equivalently “SiOx” as used herein refers to a material comprising silicon and oxygen, and does not imply any specific ratio or stoichiometry of the silicon to the oxygen. In one or more embodiments, the silicon oxide is silicon dioxide (SiO₂). In one or more embodiments, the plurality of dummy dielectric interlayers comprises SiON, SiOC, or SiOC.

The plurality of dummy dielectric interlayers 428 may be formed by any method known to the skilled artisan. For example, in one or more embodiments, the plurality of dummy dielectric interlayers is formed by an epitaxial growth of the dummy dielectric interlayer material on the SiGe nanosheet 426.

In one or more embodiments, the plurality of dummy dielectric interlayers 428 is etched back to form a plurality of etched dummy dielectric interlayers 428e, as shown in FIG. 4K. The etching may be performed using any etching method known to the skilled artisan, such as any of the dry etch or wet etch methods described herein.

Referring to FIG. 3, in one or more embodiments, at operation 42, inner spacers are formed on the nanosheets. The inner spacers 429 may have a structure as shown in FIG. 4L. In one or more embodiments, the formation of the inner spacers includes a deposition of inner spacer material and an etch back of the spacer material. The inner spacers may be in line with the gate spacers 422 and dummy dielectric interlayers 428e, as illustrated schematically in FIG. 4L. In one or more embodiments, the inner spacers 429 comprise an insulating material, including the same insulating material as the gate spacers 422. In one or more embodiments, the inner spacers 429 comprise SiGe. In one or more embodiments, the inner spacers 429 may be formed by a deposition of the inner spacer material and etch back of the dummy dielectric interlayers 428.

In one or more embodiments, at operation 44 of the method 30, source material and drain material 430 is deposited in the S/D regions 419, as illustrated for example in FIG. 4M. The S/D material 430 may be deposited by any known method, such as by epitaxial growth of the S/D material 430.

In one or more embodiments, at operation 46 of method 30, the dummy dielectric interlayers are removed. For example, dummy dielectric interlayers 428e of FIG. 4M can be released by a wire-release process to form the plurality of voids 431, as illustrated in FIG. 4N. The wire-release can be performed using any suitable process known to the skilled artisan, such as a dry etch process or wet etch process as described herein.

Referring to FIG. 3, in one or more embodiments, at operation 48 of method 30, a replacement metal gate 432 and contact 440 are formed in the electronic device. In one or more embodiments, the replacement metal gate 432 may have a structure as shown in FIG. 4O. The replacement metal gate 432 may be formed from a conductive material such as titanium nitride, tungsten, cobalt, aluminum, or the like. The conductive material may be formed using any suitable deposition process such as atomic layer deposition in order to ensure that the replacement metal gate 432 has a uniform thickness. The replacement metal gate 432 may be surrounded by a high-k dielectric layer 433. The high-k dielectric layer 433 can be any suitable high-k dielectric material deposited by any suitable deposition method known to the skilled artisan. In one or more embodiments, the high-k dielectric material is hafnium oxide.

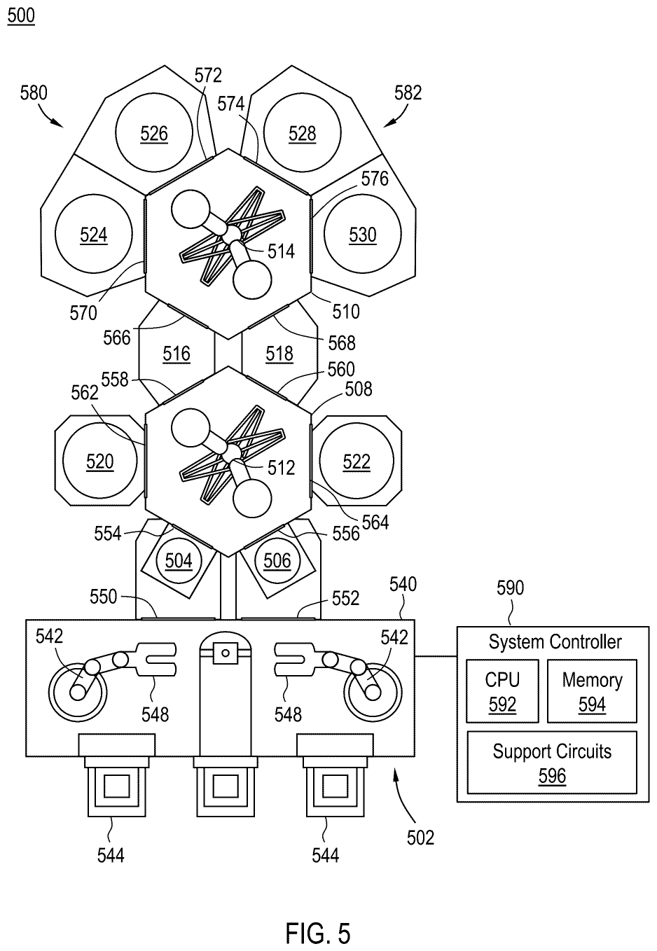

One or more embodiments of the disclosure are directed to integrated processes which are performed within a single cluster tool. FIG. 5 illustrates a schematic top-view diagram of an example of a multi-chamber processing system 500 according to embodiments of the present disclosure. The processing system 500 generally includes a factory interface 502, load lock chambers 504, 506, transfer chambers 508, 510 with respective transfer robots 512, 514, holding chambers 516, 518, and processing chambers 520, 522, 524, 526, 528, and 530. As detailed herein, wafers in the processing system 500 can be processed in and transferred between the various chambers without exposing the wafers to an ambient environment exterior to the processing system 500 (e.g., an atmospheric ambient environment such as may be present in a fab). For example, the wafers can be processed in and transferred between the various chambers in a low pressure (e.g., less than or equal to about 300 Torr) or vacuum environment without breaking the low pressure or vacuum environment between various processes performed on the wafers in the processing system 500. Accordingly, the processing system 400 may provide for an integrated solution for some processing of wafers.

In the illustrated example of FIG. 5, the factory interface 502 includes a docking station 540 and factory interface robots 542 to facilitate transfer of wafers. The docking station 540 is configured to accept one or more front opening unified pods (FOUPs) 544. In some examples, each factory interface robot 542 generally comprises a blade 548 disposed on one end of the respective factory interface robot 542 configured to transfer the wafers from the factory interface 502 to the load lock chambers 504, 506.

The load lock chambers 504, 506 have respective ports 550, 552 coupled to the factory interface 502 and respective ports 554, 556 coupled to the transfer chamber 508. The transfer chamber 508 further has respective ports 558, 560 coupled to the holding chambers 516, 518 and respective ports 562, 564 coupled to processing chambers 520, 522. Similarly, the transfer chamber 510 has respective ports 566, 568 coupled to the holding chambers 516, 518 and respective ports 570, 572, 574, 576 coupled to processing chambers 524, 526, 528, 530. The ports 554, 556, 558, 560, 562, 564, 566, 568, 570, 572, 574, 576 can be, for example, slit valve openings with slit valves for passing wafers therethrough by the transfer robots 512, 514 and for providing a seal between respective chambers to prevent a gas from passing between the respective chambers. Generally, any port is open for transferring a wafer therethrough. Otherwise, the port is closed.

The load lock chambers 504, 506, transfer chambers 508, 510, holding chambers 516, 518, and processing chambers 520, 522, 524, 526, 528, 530 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 542 transfers a wafer from a FOUP 544 through a port 550 or 552 to a load lock chamber 504 or 506. The gas and pressure control system then pumps down the load lock chamber 504 or 506. The gas and pressure control system further maintains the transfer chambers 508, 510 and holding chambers 516, 518 with an interior low pressure or vacuum environment (which may include an inert gas). Hence, the pumping down of the load lock chamber 504 or 506 facilitates passing the wafer between, for example, the atmospheric environment of the factory interface 502 and the low pressure or vacuum environment of the transfer chamber 508.

With the wafer in the load lock chamber 504 or 506 that has been pumped down, the transfer robot 512 transfers the wafer from the load lock chamber 504 or 506 into the transfer chamber 508 through the port 554 or 556. The transfer robot 512 is then capable of transferring the wafer to and/or between any of the processing chambers 520, 522 through the respective ports 562, 564 for processing and the holding chambers 516, 518 through the respective ports 558, 560 for holding to await further transfer. Similarly, the transfer robot 514 is capable of accessing the wafer in the holding chamber 516 or 518 through the port 566 or 568 and is capable of transferring the wafer to and/or between any of the processing chambers 524, 526, 528, 530 through the respective ports 570, 572, 574, 576 for processing and the holding chambers 516, 518 through the respective ports 566, 568 for holding to await further transfer. The transfer and holding of the wafer within and among the various chambers can be in the low pressure or vacuum environment provided by the gas and pressure control system.

The processing chambers 520, 522, 524, 526, 528, 530 can be any appropriate chamber for processing a wafer. In one or more embodiments, the processing chamber 520 can be capable of performing an annealing process, the processing chamber 522 can be capable of performing a cleaning process, and the processing chambers 524, 526, 528, 530 can be capable of performing epitaxial growth processes. In some examples, the processing chamber 522 can be capable of performing a cleaning process, the processing chamber 520 can be capable of performing an etch process, and the processing chambers 524, 526, 528, 530 can be capable of performing respective epitaxial growth processes.

A system controller 590 is coupled to the processing system 500 for controlling the processing system 500 or components thereof. For example, the system controller 590 may control the operation of the processing system 500 using a direct control of the chambers 504, 506, 508, 516, 518, 510, 520, 522, 524, 526, 528, 530 of the processing system 500 or by controlling controllers associated with the chambers 504, 506, 508, 516, 518, 510, 520, 522, 524, 526, 528, 530. In operation, the system controller 590 enables data collection and feedback from the respective chambers to coordinate performance of the processing system 500.

The system controller 490 generally includes a central processing unit (CPU) 592, memory 594, and support circuits 596. The CPU 592 may be one of any form of a general-purpose processor that can be used in an industrial setting. The memory 594, or non-transitory computer-readable medium, is accessible by the CPU 592 and may be one or more of memory such as random-access memory (RAM), read only memory (ROM), floppy disk, hard disk, or any other form of digital storage, local or remote. The support circuits 596 are coupled to the CPU 592 and may comprise cache, clock circuits, input/output subsystems, power supplies, and the like. The various methods disclosed herein may generally be implemented under the control of the CPU 592 by the CPU 592 executing computer instruction code stored in the memory 594 (or in memory of a particular process chamber) as, for example, a software routine. When the computer instruction code is executed by the CPU 592, the CPU 592 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 508, 510 and the holding chambers 516, 518. In other examples, more or fewer transfer chambers (e.g., one transfer chamber) and/or more or fewer holding chambers (e.g., no holding chambers) may be implemented as a transfer apparatus in a processing system.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

1. A method of forming a semiconductor device, the method comprising:
forming a superlattice structure on a substrate, the superlattice structure comprising a plurality of first layers of a first material and a corresponding plurality of second layers of a second material, the first layers and the second layers being alternatingly arranged in a plurality of stacked pairs;
forming one or more gate and gate spacers in a gate region on the substrate and the superlattice structure;
forming a plurality of nanosheets from the superlattice structure, the plurality of nanosheets separated by a corresponding plurality of voids between each nanosheet;
filling the corresponding plurality of voids with a plurality of dummy dielectric interlayers;
etching the plurality of nanosheets between the one or more gate and gate spacers to form one or more source regions and one or more drain regions;
forming an inner spacer on the plurality of dummy dielectric interlayers; and
depositing a source material in the one or more source regions and a drain material in the one or more drain regions.

2. The method of claim 1, wherein a top layer of the superlattice structure is a first layer, the plurality of first layers comprises silicon germanium, and the plurality of second layers comprises silicon.

3. The method of claim 1, wherein the plurality of dummy dielectric interlayers comprises silicon oxide.

4. The method of claim 3, further comprising removing the plurality of dummy dielectric interlayers after depositing the source material and the drain material.

5. The method of claim 1, wherein the first material of the first layer comprises silicon germanium and the second material of the second layer comprises silicon, or the first material of the first layer comprises silicon and the second material of the second layer comprises silicon germanium.

6. The method of claim 1, wherein forming the plurality of nanosheets from the superlattice structure comprises:
selectively etching the superlattice structure to form the plurality of nanosheets and the corresponding plurality of voids, the plurality of nanosheets comprising the second material;
depositing a cladding material around each of the plurality of nanosheets;
dry oxidizing the plurality of nanosheets to form a plurality of oxide layers surrounding the cladding material; and
annealing the plurality of nanosheets to remove the second material to form the plurality of nanosheets comprising the cladding material.

7. The method of claim 6, wherein the second material comprises silicon.

8. The method of claim 6, wherein the cladding material comprises silicon germanium.

9. The method of claim 6, wherein forming the plurality of nanosheets further comprises trimming the plurality of nanosheets before depositing the cladding material.

10. The method of claim 6, wherein forming the plurality of nanosheets further comprises forming a dielectric cap before the annealing and removing the dielectric cap after the annealing.

11. The method of claim 6, wherein a temperature of the annealing is in a range of from about 600° C. to about 1100° C.

12. The method of claim 1, further comprising forming a replacement metal gate in the gate region and forming a contact on one or more of the source material and one or more of the drain material.

13. A method of forming a semiconductor device, the method comprising:
forming a superlattice structure on a substrate, the superlattice structure comprising a plurality of first layers of a first material and a corresponding plurality of second layers of a second material, the first layers and the second layers being alternatingly arranged in a plurality of stacked pairs;
forming one or more gate and gate spacers in a gate region on the substrate and the superlattice structure;
etching the superlattice structure between the one or more gate and gate spacers to form an etched superlattice structure, and to form one or more source regions and one or more drain regions;
forming a plurality of nanosheets from the etched superlattice structure, the plurality of nanosheets separated by a corresponding plurality of voids between each nanosheet;
filling the corresponding plurality of voids with a plurality of dummy dielectric interlayers;
forming an inner spacer on the plurality of dummy dielectric interlayers; and
depositing a source material in the one or more source regions and a drain material in the one or more drain regions.

14. The method of claim 13, wherein a top layer of the superlattice structure is a first layer, the plurality of first layers comprises silicon germanium, and the plurality of second layers comprises silicon oxide.

15. The method of claim 13, wherein the plurality of dummy dielectric interlayers comprises silicon oxide.

16. The method of claim 15, further comprising removing the plurality of dummy dielectric interlayers after depositing the source material and the drain material.

17. The method of claim 13, wherein the first material of the first layer comprises silicon germanium and the second material of the second layer comprises silicon, or the first material of the first layer comprises silicon and the second material of the second layer comprises silicon germanium.

18. The method of claim 13, wherein forming the plurality of nanosheets from the superlattice structure comprises:
selectively etching the superlattice structure to form the plurality of nanosheets and the corresponding plurality of voids, the plurality of nanosheets comprising the second material, the second material comprising silicon;
depositing a cladding material around each of the plurality of nanosheets, the cladding material comprising silicon germanium;
dry oxidizing the plurality of nanosheets to form a plurality of oxide layers surrounding the cladding material; and
annealing the plurality of nanosheets to remove the second material to form the plurality of nanosheets comprising the cladding material, wherein a temperature of the annealing is in a range of from about 600° C. to about 1100° C.

19. The method of claim 18, wherein forming the plurality of nanosheets further comprises trimming the plurality of nanosheets before depositing the cladding material.

20. The method of claim 18, wherein forming the plurality of nanosheets further comprises forming a dielectric cap before the annealing and removing the dielectric cap after the annealing.
